(19) United States
(12) Patent Application Publication
(10) Pub. No.: US 2011/0220188 A1
(43) Pub. Date: Sep. 15, 2011

(54) Dye Sensitized Photovoltaic Cell

(75) Inventors: Christoph Josef Brabec, Linz (AT); Kethinni G. Chittibabu, Westford, MA (US); David Waller, Lexington, MA (US)

(73) Assignee: Konarka Technologies, Inc., Lowell, MA (US)

(21) Appl. No.: 13/106,068

(22) Filed: May 12, 2011

Related U.S. Application Data
(63) Continuation of application No. PCT/US2009/064156, filed on Nov. 12, 2009.
(60) Provisional application No. 61/115,648, filed on Nov. 18, 2008.

(51) Int. Cl. H01L 31/02; H01L 51/44

(52) U.S. Cl. 136/252

(57) ABSTRACT

Solid state dye sensitized photovoltaic cells, as well as related components, systems, and methods, are disclosed.

### CROSS REFERENCE TO RELATED APPLICATIONS

Pursuant to 35 U.S.C. §120, this application is a continuation of and claims priority to International Application No. PCT/US2009/064156, filed Nov. 12, 2009, which claims priority to U.S. Provisional Application Ser. No. 61/115,648, filed Nov. 18, 2008. The contents of the prior applications are hereby incorporated by reference.

### TECHNICAL FIELD

This disclosure relates to dye sensitized photovoltaic cells (e.g., hybrid dye sensitized photovoltaic cells), as well as related components, systems, and methods.

### BACKGROUND

Photovoltaic cells, sometimes called solar cells, can convert light, such as sunlight, into electrical energy. A typical photovoltaic cell includes a photovoltaically active material disposed between two electrodes. Generally, light passes through one or both of the electrodes to interact with the photovoltaically active material, which generates excited electrons that are eventually transferred to an external load in the form of electrical energy. One type of photovoltaic cell is a dye sensitized solar cell (DSSC).

### SUMMARY

In one aspect, this disclosure features articles that include first and second electrodes, and a photovoltaically active layer between the first and second electrodes. The photovoltaically active layer includes titanium oxide nanoparticles. The nanoparticles have an average particle diameter of at least about 20 nm. The article is configured as a solid state photovoltaic cell.

In another aspect, this disclosure features articles that include first and second electrodes, and a photovoltaically active layer between the first and second electrodes. The photovoltaically active layer includes a metal oxide, a dye, and a proton scavenger. The article is configured as a photovoltaic cell.

In still another aspect, this disclosure features methods that include (1) disposing a dye, composition onto a first layer including metal oxide nanoparticles to form a photovoltaically active layer, and (2) disposing additional components onto the photovoltaically active layer to provide a photovoltaic cell. The dye composition contains a dye and a solvent. The solvent can include an alcohol.

Embodiments can include one or more of the following features.

The nanoparticles, can have an average particle diameter of at most 100 nm (e.g., between about 25 nm and about 60 nm).

The photovoltaically active layer can have a thickness of at least about 500 nm and/or at most about 10 microns.

The photovoltaically active layer can further include a dye. In some embodiments, the dye has a molar extinction coefficient of at least about 8,000.

The photovoltaically active layer and/or dye composition can further include a proton scavenger. In some embodiments, the proton scavenger includes a guanidino-alkanoic acid (e.g., a guanidino-butyric acid).

The articles described above can further include a hole carrier layer between the photovoltaically active layer and the second electrode. The hole carrier layer can include a material selected from the group consisting of spiro-MeO-TAD, triaryl amines, polythiophenes, polyanilines, polycarbazoles, polyvinylcarbazoles, polyphenylenes, polyphenylvinylenes, polysilanes, polythienylenevinylenes, polyisothianaphthanenes, and copolymers or mixtures thereof. For example, the hole carrier layer can include poly(3-hexylthiophene) (P3HT) or poly(3,4-ethylenedioxythiophene) (PEDOT).

The articles described above can further include a hole blocking layer between the photovoltaically active layer and the first electrode. The hole blocking layer can include LiF, metal oxides, or amines. In some embodiments; the hole blocking layer includes a non-porous metal oxide (e.g., TiO₂) layer.

The articles described above can be configured as a solid state photovoltaic cell.

The metal oxide in the photovoltaically active layer can be in the form of nanoparticles. The metal oxide nanoparticles can be formed from a composition containing a base and a precursor of the metal oxide. In certain embodiments, the metal oxide is selected from the group consisting of titanium oxides, tin oxides, niobium oxides, tungsten oxides, zinc oxides, zirconium oxides, lanthanum oxides, tantalum oxides, terbium oxides, and combinations thereof.

The alcohol can include a primary alcohol, a secondary alcohol, or a tertiary alcohol. For example, the alcohol can include methanol, ethanol, propanol, or 2-methoxy propanol.

The solvent can further include a cyclic ester (e.g., γ-butyrolactone).

The dye composition can further include a proton scavenger (e.g., a guanidino-alkanoic acid).

The first layer can be supported by a first electrode. In some embodiments, the methods described above can further include disposing a hole blocking layer between the first electrode and the first layer prior to disposing the dye composition.

Disposing additional components can include disposing a hole carrier layer onto the photovoltaically active layer. In some embodiments, disposing additional components further includes disposing a second electrode onto the hole carrier layer.

Embodiments can include one or more of the following advantages.

Without wishing to be bound by theory, it is believed that a photovoltaically active layer containing nanoparticles with a relatively large average diameter (e.g., larger than about 20 nm) or a photovoltaically active layer containing nanoparticles and having a relatively large porosity (e.g., at least about 40%) can facilitate filling of solid state hole carrier materials into pores between nanoparticles, thereby improving separation of the charges generated in the photovoltaically active layer. Such nanoparticles can also improve electron diffusion due to reduced particle-particle interfaces, which limit electron conduction.

Without wishing to be bound by theory, it is believed that forming a dye monolayer on metal oxide nanoparticles in a photovoltaically active layer can prevent direct contact between the metal oxide (e.g., TiO₂) with a conjugated semiconductor polymer in a hole carrier layer, thereby reducing the recombination between electrons and holes generated in a photovoltaically active layer during use and increasing the open circuit voltage and efficiency of a photovoltaic cell.

Without wishing to be bound by theory, it is believed that a proton scavenger facilitates removing protons on the metal oxide surface, thereby reducing electron-hole recombination rates and increase the open circuit voltage and efficiency of a photovoltaic cell.

Other features, objects, and advantages of the invention will be apparent from the description, drawings, and claims.

### DESCRIPTION OF DRAWINGS

FIG. 1 is a cross-sectional view of a solid state dye sensitized photovoltaic cell.

FIG. 2 is a schematic of a system containing multiple photovoltaic cells electrically connected in series.

FIG. 3 is a schematic of a system containing multiple photovoltaic cells electrically connected in parallel.

Like reference symbols in the various drawings indicate like elements.

### DETAILED DESCRIPTION

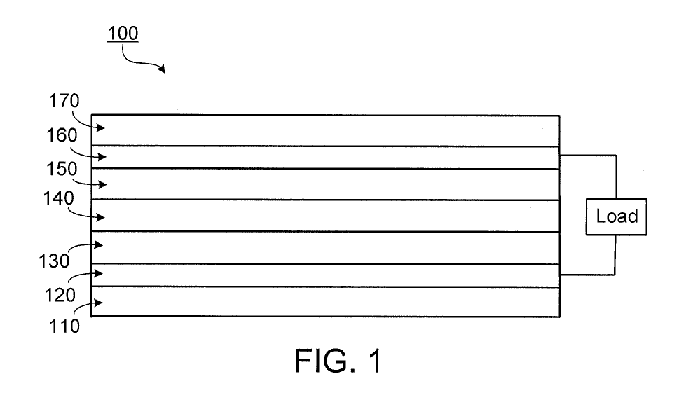

FIG. 1 shows, a dye sensitized photovoltaic cell 100 having a substrate 110, an electrode, 120, a hole blocking layer 130, a photovoltaically active layer 140, a hole carrier layer 150, an electrode 160, a substrate 170, an electrical connection between electrodes 120 and 160, and an external load electrically connected to photovoltaic cell 100 via electrodes 120 and 160. Photovoltaically active layer 140 can include a semiconductor material (e.g., TiO₂ particles) and a dye associated with the semiconductor material. In some embodiments, photovoltaically active layer 140 includes an inorganic semiconductor (e.g., dye sensitized TiO₂) and hole carrier layer 150 includes an organic hole carrier material (e.g., P3HT or PEDOT). Such a photovoltaic cell is generally known as an organic-inorganic hybrid solar cell.

In general, when each layer in a photovoltaic cell is in a solid state (e.g., a solid film), such a photovoltaic cell is referred to as a solid state photovoltaic cell. When a solid state photovoltaic cell contains a dye sensitized semiconductor material (e.g., a dye sensitized semiconducting metal oxide), such a photovoltaic cell is generally referred to as a solid state dye sensitized photovoltaic cell. In some embodiments, photovoltaic cell 100 is a solid state photovoltaic cell (e.g., a solid state dye sensitized photovoltaic cell).

Photovoltaically active layer 140 generally includes a semiconductor material and a dye associated with the semiconductor material.

In some embodiments, the semiconductor material includes metal oxides, such as titanium oxides, tin oxides, niobium oxides, tungsten oxides, zinc oxides, zirconium oxides, lanthanum oxides, tantalum oxides, terbium oxides, or combinations thereof. In certain embodiments, the metal oxides include a titanium oxide, a zinc stannate, or a niobium titanate. Other suitable semiconductor materials have been described in, for example, commonly-owned co-pending U.S. Application Publication Nos. 2006-0130895 and 2007-0224464, the contents of which are hereby incorporated by reference.

In some embodiments, the metal oxide is in the form of nanoparticles. The nanoparticles can have an average diameter of at least about 20 nm (e.g., at least about 25 nm, at least about 30 nm, or at least about 50 nm) and/or at most about 100 nm (e.g., at most about 80 nm or at most about 60 nm). Preferably, the nanoparticles can have an average diameter between about 25 nm and about 60 nm. Without wishing to be bound by theory, it is believed that nanoparticles with a relatively large average diameter (e.g., larger than about 20 nm) can facilitate filling of solid state hole carrier materials into pores between nanoparticles, thereby improving separation of the charges generated in photovoltaically active layer 140. Without wishing to be bound by theory; it is believed that nanoparticles with a relatively large average diameter (e.g., larger than about 20 nm) can improve electron diffusion due to reduced particle-particle interfaces, which limit electron conduction. Finally, without wishing to be bound by theory, it is believed that nanoparticles with an average diameter larger than A certain size (e.g., larger than about 100 nm) may reduce the surface area of the nanoparticles and thereby reducing the short circuit current.

In some embodiments, the metal oxide nanoparticles can be formed by treating (e.g., heating) a precursor composition containing a precursor of the metal oxide and an acid or a bast. Preferably, the metal oxide nanoparticles are formed from the precursor composition containing a base. In certain embodiments, the precursor composition can further include a solvent (e.g., water or an aqueous solvent).

In some embodiments, the base can include an amine, such as tetraalkyl ammonium hydroxide (e.g., tetramethyl ammonium hydroxide (TMAH), tetraethyl ammonium hydroxide, or tetra cetyl ammonium hydroxide), triethanolamine, diethylenetriamine, ethylenediamine, trimethylenediamine, or triethylenetetramine. In certain embodiments, the composition contains at least about 0.05 M (e.g., at least about 0.2 M, at least about 0.5 M, or at least about 1 M) and/or at most about 2 M (e.g., at most about 1.5 M, at most about 1 M, or at most about 0.5 M) of the base. Without wishing to be bound by theory, it is believed that different bases can facilitate formation of metal oxide nanoparticles with different shapes. For example, it is believed that tetramethyl ammonium hydroxide facilitates formation of spherical nanoparticles, while tetracetyl ammonium hydroxide facilitates formation of rod/tube like nanoparticles.

Without wishing to be bound by theory, the morphology of metal oxide nanoparticles can be affected by the pH of the precursor composition. For example, when triethanolamine is used as a base, the morphology of TiO₂ nanoparticles can change from cuboidal to ellipsoidal at pH above about 11. As another example, when diethylenetriamine is used as a base, the morphology of TiO₂ nanoparticles can change into ellipsoidal at pH above about 9.5. By contrast, without wishing to be bound by theory, it is believed that when metal oxide nanoparticles are formed in the presence of an acid, the nature and amount of the acid would not affect the morphology of the nanoparticles.

Without wishing to be bound by theory, it is believed that metal oxide nanoparticles with to a large length to width aspect ratio could facilitate electron transport, thereby increasing the efficiency of a photovoltaic cell. In some embodiments, metal oxide nanoparticles in photovoltaically active layer 140 has a length to width aspect ratio of at least about 1 (e.g., at least about 5, at least about 10, least about 50, at least about 100, or at least about 500).

In some embodiments, the metal oxide precursor can include a material selected from the group consisting of metal alkoxides, polymeric derivatives of metal alkoxides, metal diketonates, metal salts, and combinations thereof. Exemplary metal alkoxides include titanium alkoxides (e.g., titanium tetraisopropoxide), tungsten alkoxides, zinc alkoxides, or zirconium alkoxides. Exemplary polymeric derivatives of metal alkoxides include poly(n-butyl titanate). Exemplary metal diketonates include titanium oxyacetylacetonate or titanium bis(ethyl acetoacetato)diisopropoxide. Exemplary metal salts include metal halides (e.g., titanium tetrachloride), metal bromides, metal fluorides, metal sulfates, or metal nitrates. In certain embodiments, the precursor composition contains at least about 0.1 M (e.g., at least about 0.2 M, at least about 0.3 M, or at least about 0.5 M) and/or at most about 2 M (e.g., at most about 1 M, at most about 0.7 M, or at most about 0.5 M) of the metal oxide precursor

Methods of forming the precursor composition can vary as desired. In some embodiments, the precursor composition can be formed by adding an aqueous solution of a metal oxide precursor (e.g., titanium tetraisopropoxide) into an aqueous solution of a base (e.g., TMAH).

After the precursor composition is formed, it can undergo thermal treatment to form metal oxide nanoparticles. In some embodiments, the composition can first be heated to an intermediate temperature from about 60° C. to about 100° C. (e.g., about 80° C.) for a sufficient period of time (e.g., from about 7 hours to 9 hours, such as 8 hours) to form a peptized sol. Without wishing to be bound by theory, it is believed that heating the precursor composition at such an intermediate temperature for a period of time can facilitate sol formation. In certain embodiments, the peptized sol can be further heated at a high temperature from about 200° C. to about 250° C. (e.g., about 230° C.) for a sufficient period of time (e.g., from about 10 hours to 14 hours, such as 12 hours) to form metal oxide nanoparticles with a desired average particle size (e.g., an average diameter between about 25 nm and about 60 nm). Without wishing to be bound by theory, it is believed that heating the peptized sol at such a high temperature for a period of time can increase the size of the nanoparticles thus formed to at least about 20 nm and improve the mechanical and electronic properties of these nanoparticles.

In some embodiments, the metal oxide nanoparticles in photovoltaically active layer 140 can be interconnected, for example, by high temperature sintering or by a reactive polymeric linking agent, such as poly(n-butyl titanate). A polymeric linking agent can enable the fabrication of an interconnected nanoparticle layer at relatively low temperatures (e.g., less than about 300° C.) and in some embodiments at room temperature. In some embodiments, the polymeric linking agent can be added to the precursor composition. The relatively low temperature interconnection process can be amenable to continuous manufacturing processes (e.g., a roll-to-roll manufacturing process) using polymer substrates.

After the thermal treatment, the precursor composition can be converted into a printable paste. In some embodiments, the printable paste can be obtained by concentrating the precursor composition containing the metal oxide nanoparticles formed above and then adding an additive (e.g. terpineol and/or ethyl cellulose) to the concentrated composition. The printable paste can then be applied onto another layer in a photovoltaic cell (e.g., an electrode or a hole blocking layer) to form photovoltaically active layer 140. The printable paste can be applied by a liquid-based coating processing discussed in more detail below.

Other suitable methods for preparing metal oxide nanoparticles have been described in, for example, commonly-owned co-pending U.S. Provisional Application No. 61/041,367, the contents of which are hereby incorporated by reference.

In some embodiments, photovoltaically active layer 140 is a porous layer containing metal oxide nanoparticles. In such embodiments, photovoltaically active layer 140 can have a porosity of at least about 40% (e.g., at least about 50% or at least about 60%) and/or at most about 70% (e.g., at most about 60% or at most about 50%). Without wishing to be bound by theory, it is believed that a photovoltaically active, layer containing nanoparticles and having a relatively large porosity (e.g., larger than about 40%) can facilitate diffusion of solid state hole carrier materials into pores between nanoparticles, thereby improving separation of the charges generated in the photovoltaically active layer.

The semiconductor material in photoactive layer 140 (e.g., interconnected metal oxide nanoparticles) is generally photosensitized by at least a dye (e.g., two or more dyes). The dye facilitates conversion of incident light into electricity to produce the desired photovoltaic effect. It is believed that a dye absorbs incident light, resulting in the excitation of electrons in the dye. The excited electrons are then transferred from the excitation levels of the dye into a conduction band of the semiconductor material. This electron transfer results in an effective separation of charge and the desired photovoltaic effect. Accordingly, the electrons in the conduction band of the semiconductor material are made available to drive an external load.

The dyes suitable for use in photovoltaic cell 100 can have a molar-extinction coefficient (ε) of at least about 8,000 (e.g., at least about 10,000, at least about 13,000, at least 14,000, at least about 15,000, at least about 18,000, at least about 20,000, at least about 23,000, at least about 25,000, at least about 28,000, and at least about 30,000) at a given wavelength (e.g., λₘₐₓ) within the visible light spectrum. Without wishing to be bound by theory, it is believed that dyes with a high molar extinction coefficient exhibited enhanced light absorption and therefore improves the short circuit current of photovoltaic cell 100.

Examples of suitable dyes include black dyes (e.g., tris(isothiocyanato)-ruthenium (II)-2,2′:6′,2″-terpyridine-4,4′,4″-tricarboxylic acid, tris-tetrabutylammonium salt), orange dyes (e.g., tris(2,2′-bipyridyl-4,4′-dicarboxylato) ruthenium (II) dichloride, purple dyes (e.g., cis-bis(isothiocyanato)bis-(2,2′-bipyridyl-4,4′-dicarboxylato)-ruthenium (II)), red dyes (e.g., an eosin), green dyes (e.g., a merocyanine) and blue dyes (e.g., a cyanine). Examples of black dyes have also been described in commonly-owned co-pending U.S. application Ser. No. 12/236,150, the contents of which are hereby incorporated by reference. Examples of additional dyes include anthocyanines, porphyrins, phthalocyanines, squarates, and certain metal-containing dyes. Commercially available dyes and dyes reported in the literature include Z907, K19, K51, K60, K68, K77, K78, N3, and N719. Combinations of dyes can also be used within a given region so that a given region can include two or more (e.g., two, three, four, five, six, seven) different dyes.

The dye can be sorbed (e.g., chemisorbed and/or physisorbed) onto the semiconductor material. The dye can be selected, for example, based on its ability to absorb photons in a wavelength range of operation (e.g., within the visible spectrum), its ability: to produce free electrons (or holes) in a conduction band of the nanoparticles, its effectiveness in complexing with or sorbing to the nanoparticles, and/or its color. In some embodiments, the dye can be sorbed onto the semiconductor material (e.g., a metal oxide) by immersing an intermediate article (e.g., an article containing a substrate, an electrode, a hole blocking layer, and a semiconductor material) into a dye composition for a sufficient period of time (e.g., at least about 12 hours).

In some embodiments, the dye composition can form a monolayer on metal oxide nanoparticles. Without wishing to be bound by theory, it is believed that forming a dye monolayer can prevent direct contact between the metal oxide (e.g., TiO₂) with a conjugated semiconductor polymer in hole carrier layer 150, thereby reducing recombination between electrons and holes generated in photovoltaically active layer 140 during use and increasing the open circuit voltage and efficiency of photovoltaic cell 100.

In general, the dye composition includes a solvent, such as an organic solvent. Suitable solvents for the photosensitizing agent composition include alcohols (e.g., primary alcohols, secondary alcohols, or tertiary alcohols). Examples of suitable alcohols include methanol, ethanol, propanol, and 2-methoxy propanol. In some embodiments, the solvent can further include a cyclic ester, such as a γ-butyrolactone. Without wishing to be bound by theory, it is believed that using a solvent (e.g., an alcohol) in which the dye has a relatively poor solubility (e.g., a solubility of at most about 8 mM at room temperature) facilitates formation of a dye monolayer on the metal oxide layer, thereby reducing the recombination between electrons and, holes generated in photovoltaically active layer 140 during use. In some embodiments, suitable solvents are those in which the dye has a solubility of at most about 8 mM (e.g., at most about 1 mM) at room temperature.

In some embodiments, the dye composition further includes a proton scavenger. As used herein, the term “proton scavenger” refers to any agent that is capable of binding to a proton. An example of a proton scavenger is a guanidino-alkanoic acid (e.g., 3-guanidino-propionic acid or guanidine-butyric acid). Without wishing to be bound by theory, it is believed that a proton scavenger facilitates removing protons on the metal oxide surface, thereby reducing electron-hole recombination rates and increase the open circuit voltage and efficiency of photovoltaic cell 100.

The thickness of photovoltaically active layer 140 can generally vary as desired. For example, photovoltaically active layer 140 can have a thickness of at least about 500 nm at least about 1 micron, at least about 2 microns, or at least about 5 microns) and/or at most about 10 microns (e.g., at most about 8 microns, at most about 6 microns, or at most about 4 microns). Without wishing to be bound by theory, it is believed that photovoltaically active layer 140 having a relative large thickness (e.g., larger than about 2 microns) can have improved light absorption, thereby improving the current density and performance of a photovoltaic cell. Further, without wishing to be bound by theory, it is believed that photovoltaically active layer 140 having a thickness larger than a certain size (e.g., larger than 4 microns) may exhibit reduced charge separation as the thickness can be larger than the diffusion length of the charges-generated by the photovoltaic cell during use.

In some embodiments, photovoltaically active layer 140 can be formed by applying a composition containing metal oxide nanoparticles onto a substrate by a liquid-based coating process. The term “liquid-based coating process” mentioned herein refers, to a process that uses a liquid-based coating composition. Examples of liquid-based coating compositions include solutions, dispersions, and suspensions (e.g., printable pastes).

The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Without wishing to be bound by theory, it is believed that the liquid-based coating process can be readily used in a continuous manufacturing process, such as a roll-to-roll process, thereby significantly reducing the cost of preparing a photovoltaic cell. Examples of roll-to-roll processes have been described in, for example, commonly-owned co-pending U.S. Application Publication No. 2005-0263179, the contents of which are hereby incorporated by reference.

The liquid-based coating process can be carried out either at room temperature, or at an elevated-temperature (e.g., at least about 50° C., at least about 100° C., at least about 200° C., or at least about 300° C.). The temperature can be adjusted depending on various factors, such as the coating process and the coating composition used. In some embodiments, nanoparticles in the coated paste can be sintered at a high temperature (e.g., at least about 300° C.) to form interconnected nanoparticles. On the other hand, in certain embodiments, when a polymeric linking agent (e.g., poly(n-butyl titanate)) is added to the inorganic nanoparticles, the sintering process can be carried out at a lower temperature (e.g., below about 300° C.).

For example, photovoltaically active layer 140 can be prepared as follows: Metal oxide nanoparticles (e.g., TiO₂ nanoparticles) can be formed by treating (e.g., heating) a composition (e.g., a dispersion) containing a precursor of the metal oxide (e.g., a titanium alkoxide such as titanium tetraisopropoxide) in the presence of an acid or a base. The composition typically includes a solvent (e.g., such as water or an aqueous solvent). After the treatment, the composition can be converted into a printable paste. In some embodiments, the printable paste can be obtained by concentrating the composition containing the metal oxide nanoparticles formed above and then adding an additive (e.g., terpineol and/or ethyl cellulose) to the concentrated composition. The printable paste can then be coated onto another layer in a photovoltaic cell (e.g., an electrode or a hole blocking layer) and then be treated (e.g., by high temperature sintering) to form a porous layer containing interconnected metal oxide nanoparticles. Photovoltaically active layer 140 can subsequently be formed by adding a dye composition (e.g., containing a dye, a solvent, and a proton scavenger) to the porous layer to sensitize the metal oxide nanoparticles.

Turning to other components in photovoltaic cell 100, substrate 110 is generally formed of a transparent material. As referred to herein, a transparent material is a material which, at the thickness used in a photovoltaic cell 100, transmits at least about 60% (e.g., at least about 70%, at least about 75%, at least about 80%, or at least about 85%) of incident light at a wavelength or a range of wavelengths used during operation of the photovoltaic cell. Exemplary materials from which substrate 110 can be formed include glass, polyethylene terephthalates, polyimides, polyethylene naphthalates, polymeric hydrocarbons, cellulosic polymers, polycarbonates, polyamides, polyethers, and polyether ketones. In certain embodiments, the polymer can be a fluorinated polymer. In some embodiments, combinations of polymeric materials are used. In certain embodiments, different regions of substrate 110 can be formed of different materials.

In general, substrate 110 can be flexible, semi-rigid or rigid (e.g., glass). In some embodiments, substrate 110 has a flexural modulus of less than about 5,000 megaPascals less than about 1,000 megaPascals or less than about 500 megaPascals). In certain embodiments, different regions of substrate 110 can be flexible, semi-rigid, or inflexible (e.g., one or more regions flexible and one or more different regions semi-rigid, one or more regions flexible and one or more different regions inflexible).

Typically, substrate 110 is at least about one micron (e.g., at least about five microns or at least about 10 microns) thick and/or at most about 1,000 microns (e.g., at most about 500 microns thick, at most about 300 microns thick, at most about 200 microns thick, at most about 100 microns, or at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Electrode 120 is generally formed of an electrically-conductive material. Exemplary electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum, and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., doped poly(3,4-ethylenedioxythiophene) (doped PEDOT)), polyanilines (e.g., doped polyanilines), polypyrroles (e.g., doped polypyrroles). Exemplary electrically conducting metal oxides include indium tin oxide, fluorinated tin oxide, tin oxide and zinc oxide. In some embodiments, combinations of electrically conductive materials are used.

In some embodiments, electrode 120 can include a mesh electrode. Examples of mesh electrodes are described in co-pending U.S. Patent Application Publication Nos. 2004-0187911 and 2006-0090791, the entire contents of which are hereby incorporated by reference.

Optionally, photovoltaic cell 100 can include a hole blocking layer 130. The hole blocking layer is generally formed of a material that, at the thickness used in photovoltaic cell 100, transports electrons to electrode 120 and substantially blocks the transport of holes to electrode 120. Examples of materials from which the hole blocking layer can be formed include LiF, metal oxides (e.g., zinc oxide, titanium oxide), and amines (e.g., primary, secondary, or tertiary amines). Examples of amines suitable for use in a hole blocking layer have been described, for example, in commonly-owned co-pending U.S. Application Publication No. 2008-0264488, the entire contents of which are hereby incorporated by reference.

Typically, hole blocking layer 130 is at least 0.02 micron (e.g., at least about 0.03 micron, at least about 0.04 micron, or at least about 0.05 micron) thick and/or at most about 0.5 micron, at most about 0.4 micron, at most about 0.3 micron, at most about 0.2 micron, or at most about 0.1 micron) thick.

In some embodiments, hole blocking layer 130 can be a non-porous layer. In such embodiments, hole blocking layer 130 can be a compact layer with a small thickness (e.g., less; than about 0.1 microns).

Hole carrier layer 150 is generally formed of a material that, at the thickness used in photovoltaic cell 100, transports holes to electrode 160 and substantially blocks the transport of electrons to electrode 160. Examples of materials from which layer 150 can be formed include spiro-MeO-TAD, triaryl amines, polythiophenes (e.g., PEDOT doped with poly(styrene-sulfonate)), polyanilines, polycarbazoles, polyvinylcarbazoles, polyphenylenes, polyphenylvinylenes, polysilanes, polythienylenevinylenes, polyisothianaphthanenes, and copolymers thereof. In some embodiments, hole carrier layer 150 can include combinations of hole carrier materials.

In general, the thickness of hole carrier layer 150 (i.e., the distance between the surface of hole carrier layer 150 in contact with photoactive layer 140 and the surface of electrode 160 in contact with hole carrier layer 150) can vary as desired. Typically, the thickness of hole carrier layer 150 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some embodiments, the thickness of hole carrier layer 150 is from about 0.01 micron to about 0.5 micron.

Electrode 160 is generally formed of an electrically conductive material, such as one or more of the electrically conductive materials that can be used to form electrode 120 described above. In some embodiments, electrode 160 is formed of a combination of electrically conductive materials. In certain embodiments, electrode 160 can be formed of a mesh electrode.

In general, each of electrode 120, hole blocking layer 130, hole carrier layer 150, and electrode 160 can be prepared by a liquid-based coating process, such as one of the processes described above.

In some embodiments, when a layer (e.g., one of layers 120, 130, 150, and 160) includes inorganic nanoparticles, the liquid-based coating process can be carried out by (1) mixing the nanoparticles with a solvent (e.g., an aqueous solvent or an anhydrous alcohol) to form a dispersion, (2) coating the dispersion onto a substrate, and (3) drying the coated dispersion. In; certain embodiments, a liquid-based coating process for preparing a layer containing inorganic metal oxide nanoparticles can be carried out by (1) dispersing a precursor (e.g., a titanium salt) in a suitable solvent (e.g., an anhydrous alcohol) to form a dispersion, (2) coating the dispersion on a photoactive layer, (3) hydrolyzing the dispersion to form an inorganic metal oxide nanoparticles layer (e.g., a titanium oxide nanoparticles layer), and (4) drying the inorganic metal oxide layer. In certain embodiments, the liquid-based coating process can include a sol-gel process.

In general, the liquid-based coating process used to prepare a layer containing an organic material can be the same as or different from that used to prepare a layer containing an inorganic material. In some embodiments, when a layer (e.g., one of layers 120, 130, 150, and 160) includes an organic material, the liquid-based coating process can be carried out by mixing the organic material with a solvent (e.g., an organic solvent) to form a solution or a dispersion, coating the solution or dispersion on a substrate, and drying the coated solution or dispersion.

Substrate 170 can be identical to or different from substrate 110. In some embodiments, substrate 170 can be formed of one or more suitable polymers, such as the polymers used in substrate 110 described above.

During operation, in response to illumination by radiation (e.g., in the solar spectrum), photovoltaic cell 100 undergoes cycles of excitation, oxidation, and reduction that produce a flow of electrons across the external load. Specifically, incident light passes through at least one of substrates 110 and 170 and excites the dye in photovoltaically active layer 140. The excited, dye then injects electrons into the conduction band of the semiconductor material in photovoltaically layer active 140, which leaves the dye oxidized. The injected electrons flow through the semiconductor material and hole blocking layer 130, to electrode 120, then to the external load. After flowing through the external load, the electrons flow to electrode 160, hole carrier layer 150, and photovoltaically active layer 140, where the electrons reduce the oxidized dye molecules back to their neutral state. This cycle of excitation, oxidation, and reduction is repeated to provide continuous electrical energy to the external load.

While certain embodiments have been disclosed, other embodiments are also possible.

In some embodiments, photovoltaic cell 100 includes a cathode as a bottom electrode and an anode as a top electrode. In some embodiments, photovoltaic cell 100 can include an anode as a bottom electrode and a cathode as a top electrode.

In some embodiments, photovoltaic cell 100 can include the layers shown in FIG. 1 in a reverse order. In other words, photovoltaic cell 100 can include these layers from the bottom to the top in the following sequence: a substrate 170, an electrode 160, a hole carrier layer 150, a photoactive layer 140, a hole blocking layer 130, an electrode 120, and a substrate 110.

While photovoltaic cells have been described above, in some embodiments, the compositions and methods described herein can be used in tandem photovoltaic cells. Examples of tandem photovoltaic cells have been described in, for example, commonly-owned co-pending U.S. Application Publication Nos. 2007-0181179 and 2007-0246094, the entire contents of which are hereby incorporated by reference.

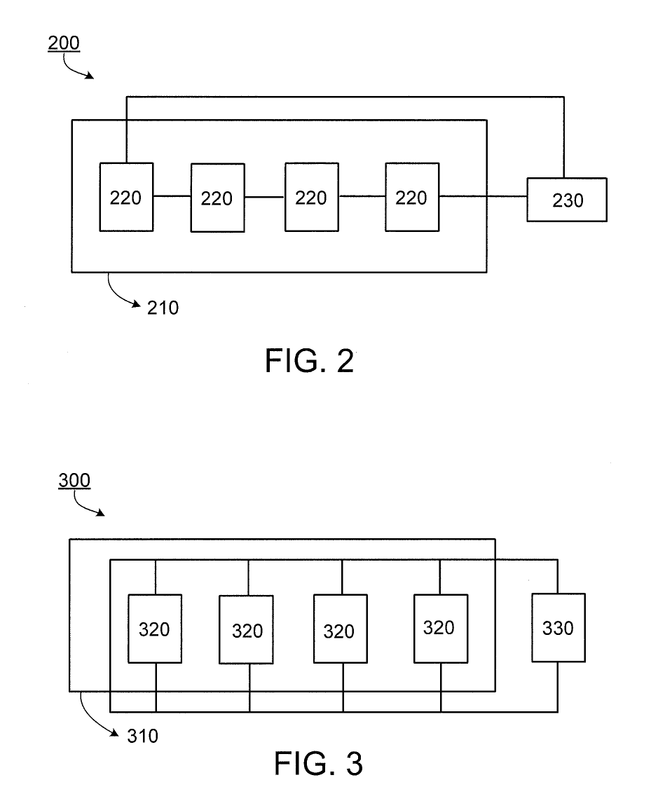

In some embodiments, multiple photovoltaic cells can be electrically connected to form a photovoltaic system. As an example, FIG. 2 is a schematic of a photovoltaic system 200 having a module 210 containing photovoltaic cells 220. Cells 220 are electrically connected in series, and system 200 is electrically connected to a load 230. As another example, FIG. 3 is a schematic of a photovoltaic system 300 having a module 310 that contains photovoltaic cells 320. Cells 320 are electrically connected in parallel, and system 300 is electrically connected to a load 330. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

While photovoltaic cells have been described above, in some embodiments, the compositions and methods described herein can be used in other electronic devices and systems. For example, they can be used in field effect transistors, photodetectors (e.g., IR detectors), photovoltaic detectors, imaging devices (e.g., RGB imaging devices for cameras or medical imaging systems), light emitting diodes (LEDs) (e.g., organic LEDs or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

The following examples are illustrative and not intended to be limiting.

### Example 1

A first type of solid state dye sensitized solar cell (SSDSSC) was prepared as follows: A solution containing 0.5 M titanium tetra-isopropoxide in ethanol was spin-coated at 2,000 rpm onto a fluorinated tin oxide (FTO) coated glass slide, followed by sintering at 450° C. for 5 minutes to form a compact titanium oxide layer with a thickness of about 30-100 nm, which served as an electron conducting hole blocking layer. An acidic colloid dispersion containing titanium oxide nanoparticles with an average diameter of about 20 nm was deposited onto the compact hole blocking layer, followed by sintering at 450° C. for 30 minutes. The sintered film was treated with a solution containing 0.05 M TiCl₄ in water for 30 minutes at 65° C. to improve necking between the nanoparticles and to reduce surface traps, followed by re-sintering at 450° C. for 2-5 minutes to form a porous titanium oxide nanoparticles layer with a thickness of about 2 microns. The sintered porous titanium oxide nanoparticles layer was sensitized by a dye composition containing Z907 and a guanidinobutyric acid (GBA) to form a photovoltaically active layer. A solution containing 1-5% poly(3-hexylthiophene) in chlorobenzne was deposited on the photovoltaically active layer to form a hole carrier layer. A 50-100 nm of gold electrode was then vacuum evaporated on top of dried hole carrier layer.

A second type of SSDSSC was prepared by the same method described above except that the porous titanium oxide nanoparticles layer was prepared by mixing Showa Denko's F2 (Showa Denko K.K., Kanagawa, Japan) with a screen printable composition and deposited onto the compact titanium oxide layer to form a porous layer containing titanium oxide nanoparticles having an average diameter of about 60 nm.

The first and second types of SSDSSCs were replicated six and seven times, respectively. The performance of the first and second types of SSDSSCs was measured at simulated 1 sun light under AM 1.5 conditions. The test results are summarized in Tables 1 and 2 below.

TABLE 1
Physical Properties of Solar Cells With 20 nm TiO₂

| | Cell size | | | Efficiency | |
|---|---|---|---|---|---|
| Sample | (cm²) | V_{oc} (V) | J_{sc} (mA/cm²) | (%) | Fill factor |
| 1 | 0.4 | 0.737 | 3.692 | 1.24 | 45.6 |
| 2 | 0.6 | 0.748 | 3.027 | 1.06 | 46.7 |
| 3 | 0.6 | 0.724 | 4.205 | 1.23 | 40.4 |
| 4 | 0.6 | 0.705 | 1.976 | 0.61 | 44.1 |
| 5 | 0.4 | 0.702 | 2.717 | 0.84 | 43.9 |
| 6 | 0.6 | 0.683 | 2.822 | 0.78 | 40.5 |
| 7 | 0.6 | 0.688 | 2.439 | 0.67 | 40.2 |
| Average | 0.55 | 0.714 | 3.183 | 0.959 | 42.36 |

TABLE 2
Physical Properties of Solar Cells With 60 nm TiO₂

| | Cell size | | | Efficiency | |
|---|---|---|---|---|---|
| Sample | (cm²) | V_{oc} (V) | J_{sc} (mA/cm²) | (%) | Fill factor |
| 1 | 0.44 | 0.796 | 3.633 | 1.52 | 52.6 |
| 2 | 0.66 | 0.816 | 3.687 | 1.51 | 50.2 |
| 3 | 0.66 | 0.811 | 3.401 | 1.38 | 50.1 |
| 4 | 0.66 | 0.782 | 4.227 | 1.59 | 48.0 |
| 5 | 0.66 | 0.796 | 4.274 | 1.77 | 52.0 |
| 6 | 0.66 | 0.811 | 4.186 | 1.68 | 49.4 |
| Average | 0.623 | 0.802 | 3.901 | 1.575 | 50.38 |

As shown in Tables 1 and 2, the SSDSSCs containing TiO₂ with an average diameter of about 60 nm exhibited significantly better performance compared to the SSDSSCs containing TiO₂ with an average diameter of about 20 nm.

### Example 2

Three dyes with high molar extinction efficiencies (ε) were incorporated into SSDSSCs: (1) a mixture of Z907 and GBA, (2) N719, and (3) K19. The chemical structures of dyes Z907, N719, and K19 are listed below:

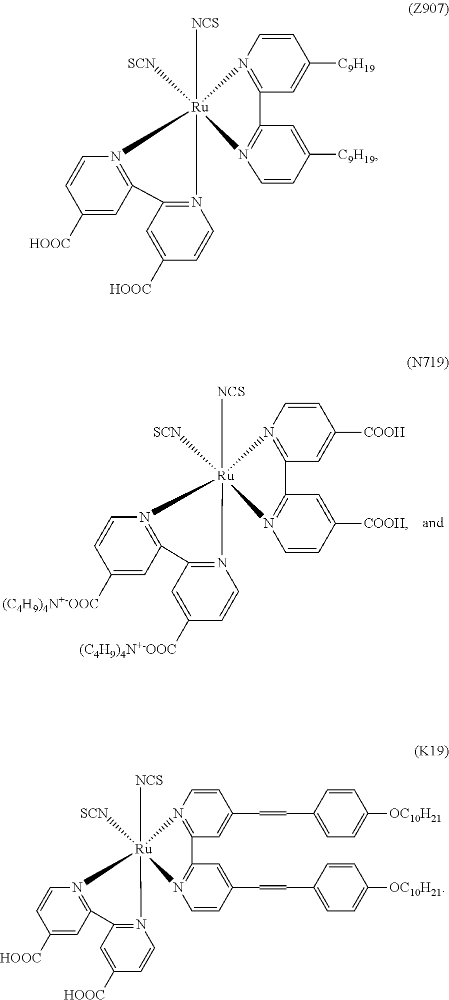

The SSDSSCs were prepared in a manner similar to that of Example 1 except that an alkaline dispersion containing titanium oxide nanoparticles having an average diameter of about 30 nm was used to prepare the photovoltaically active layer. A SSDSSC containing no dye was used as a control. Each type of solar cells was replicated 3-6 times. The performance of the SSDSSCs was measured at simulated 1 sun light under AM 1.5 conditions. The average test results are summarized in Table 3 below.

TABLE 3

| | | Cell size | | J_{sc} | Efficiency | |
|---|---|---|---|---|---|---|
| Dye | ε | (cm²) | V_{oc}(V) | (mA/cm²) | (%) | Fill factor |
| None | 0 | 0.3 | 0.43 | 0.25 | 0.037 | 36 |
| Z907- | ~8,000 | 0.3 | 0.81 | 4.18 | 1.14 | 33.4 |
| GBA | | | | | | |
| N719 | ~13,000 | 0.3 | 0.60 | 5.19 | 1.09 | 35.1 |
| K19 | ~19,000 | 0.3 | 0.61 | 5.80 | 1.18 | 33.3 |

As shown in Table 3, a SSDSSC containing a dye with a high molar extinction efficiency exhibited a high short circuit current density (J_{sc}).

### Example 3

The effect of a proton scavenger was determined by comparing the performance of SSDSSCs containing a GBA with that of SSDSSCs without a GBA. The SSDSSCs were prepared in a manner similar to that of Example 1 except that an alkaline dispersion containing, titanium oxide nanoparticles having an average diameter of about 30 nm was used to prepare the photovoltaically active layer. Each type of solar cells was replicated 4 or 5 times. The performance of the SSDSSCs was measured at simulated 1 sun light under AM1.5 conditions. The test results are summarized in Tables 4 and 5 below.

TABLE 4
Physical Properties of Solar Cells Containing a GBA

| | Cell size | | | Efficiency | |
|---|---|---|---|---|---|
| Sample | (cm²) | V_{oc} (V) | J_{sc} (mA/cm²) | (%) | Fill factor |
| 1 | 1 | 0.704 | 3.04 | 0.78 | 36.5 |
| 2 | 1 | 0.703 | 3.20 | 0.83 | 36.9 |
| 3 | 1 | 0.716 | 4.46 | 1.23 | 38.5 |
| 4 | 0.7 | 0.723 | 3.58 | 1.48 | 57 |
| 5 | 0.7 | 0.722 | 3.65 | 1.42 | 54 |
| Average | 0.88 | 0.714 | 3.58 | 1.15 | 44.58 |

TABLE 5
Physical Properties of Solar Cell Without a GBA

| | Cell size | | | Efficiency | |
|---|---|---|---|---|---|
| Sample | (cm²) | V_{oc} (V) | J_{sc} (mA/cm²) | (%) | Fill factor |
| 1 | 1 | 0.672 | 4.26 | 0.96 | 33.3 |
| 2 | 1 | 0.642 | 4.97 | 1.05 | 32.9 |
| 3 | 1 | 0.633 | 4.73 | 0.92 | 30.6 |
| 4 | 1 | 0.6 | 4.49 | 0.92 | 34.2 |
| Average | 1 | 0.64 | 4.61 | 0.96 | 32.8 |

As shown in Tables 4 and 5, the SSDSSCs containing a GBA exhibited better performance compared to the SSDSSCs without a GBA.

### Example 4

The effect of the dye solvent was determined by comparing the performance of SSDSSCs prepared by using DMF (a good solvent for the Z907 dye) as a dye solvent with that of SSDSSCs prepared by using a mixture of 2-methoxypropanol and a γ-butyrolactone (a poor solvent for the Z907 dye) as a dye solvent. The SSDSSCs were prepared in a manner similar to that of Example 1 except that an alkaline dispersion containing titanium oxide nanoparticles having an average diameter of about 30 nm was used to prepare the photovoltaically active layer. Each type of solar cells was replicated 3 or 5 times. The performance of the SSDSSCs was measured at simulated 1 sun light under AM 1.5 conditions. The test results are summarized in Tables 6 and 7 below.

TABLE 6
Physical Properties of Solar Cells Prepared by Using
DMF as a Dye Solvent

| | Cell size | | | Efficiency | |
|---|---|---|---|---|---|
| Sample | (cm²) | V_{oc} (V) | J_{sc} (mA/cm²) | (%) | Fill factor |
| 1 | 1 | 0.704 | 3.04 | 0.78 | 36.5 |
| 2 | 1 | 0.703 | 3.20 | 0.83 | 36.9 |
| 3 | 1 | 0.716 | 4.46 | 1.23 | 38.5 |
| 4 | 0.7 | 0.723 | 3.58 | 1.48 | 57 |
| 5 | 0.7 | 0.722 | 3.65 | 1.42 | 54 |
| Average | 0.88 | 0.714 | 3.58 | 1.15 | 44.58 |

TABLE 7
Physical Properties of Solar Cell by Using 2-Methoxypropanol and
γ-Butyrolactone as a Dye Solvent

| | Cell size | | | Efficiency | |
|---|---|---|---|---|---|
| Sample | (cm²) | V_{oc} (V) | J_{sc} (mA/cm²) | (%) | Fill factor |
| 1 | 0.6 | 0.851 | 3.49 | 1.06 | 35.8 |
| 2 | 0.6 | 0.841 | 4.17 | 1.61 | 46 |
| 3 | 1 | 0.839 | 4.18 | 1.55 | 44.2 |
| Average | 0.73 | 0.844 | 3.95 | 1.41 | 42 |

As shown in Tables 6 and 7, the SSDSSCs prepared by using 2-methoxypropanol and γ-butyrolactone as a dye solvent exhibited significantly better performance compared to the SSDSSCs prepared by using DMF as a dye solvent.

Other embodiments are within the scope of the following claims.

What is claimed is:

1. An article, comprising:
first and second electrodes; and
a photovoltaically active layer between the first and second electrodes, the photovoltaically active layer comprising titanium oxide nanoparticles;
wherein the nanoparticles have an average particle diameter of at least about 20 nm and the article is configured as a solid state photovoltaic cell.

2. The article of claim 1, wherein the nanoparticles have an average particle diameter of at most about 100 nm.

3. The article of claim 1, wherein the nanoparticles have an average particle diameter between about 25 nm and about 60 nm.

4. The article of claim 1, wherein the photovoltaically active layer has a thickness of at least about 500 nm.

5. The article of claim 1, wherein the photovoltaically active layer has a thickness of at most about 10 microns.

6. The article of claim 1, wherein the photovoltaically active layer further comprises a dye.

7. The article of claim 1, wherein the dye has a molar extinction coefficient of at least about 8,000.

8. The article of claim 1, wherein the photovoltaically active layer further comprises a proton scavenger.

9. The article of claim 8, wherein the proton scavenger comprises a guanidino-alkanoic acid.

10. The article of claim 1, further comprising a hole carrier layer between the photovoltaically active layer and the second electrode.

11. The article of claim 10, wherein the hole carrier layer comprises a material selected from the group consisting of spiro-MeO-TAD, triaryl amines, polythiophenes, polyanilines, polycarbazoles, polyvinylcarbazoles, polyphenylenes, polyphenylvinylenes, polysilanes, polythienylenevinylenes, polyisothianaphthanenes, and copolymers or mixtures thereof.

12. The article of claim 11, wherein the hole carrier layer comprises poly(3-hexylthiophene) or poly(3,4-ethylenedioxythiophene).

13. The article of claim 1, further comprising a hole blocking layer between the photovoltaically active layer and the first electrode.

14. The article of claim 13, wherein the hole blocking layer comprises LiF, metal oxides, or amines.

15. The article of claim 14, wherein the hole blocking layer comprises a non-porous metal oxide layer.

16. An article, comprising:
first and second electrodes; and
a photovoltaically active layer between the first and second electrodes, the photovoltaically active layer comprising a metal oxide, a dye, and a proton scavenger;
wherein the article is configured as a photovoltaic cell.

17. The article of claim 16, wherein the metal oxide is in the form of nanoparticles.

18. The article of claim 17, wherein the nanoparticles have an average particle diameter of at least about 20 nm.

19. The article of claim 17, wherein the nanoparticles have an average particle diameter of at most about 100 nm.

20. The article of claim 17, wherein the nanoparticles have an average particle diameter between about 25 nm and about 60 nm.

21. The article of claim 16, wherein the metal oxide is selected from the group consisting of titanium oxides, tin oxides, niobium oxides, tungsten oxides, zinc oxides, zirconium oxides, lanthanum oxides, tantalum oxides, terbium oxides, and combinations thereof.

22. The article of claim 16, wherein the metal oxide comprises a titanium oxide.

23. The article of claim 16, wherein the dye has a molar extinction coefficient of at least about 8,000.

24. The article of claim 16, wherein the proton scavenger comprises a guanidino-alkanoic acid.

25. The article of claim 24, wherein the guanidino-alkanoic acid comprises a guanidino-butyric acid.

26. The article of claim 16, wherein the photovoltaically active layer has a thickness of at least about 500 nm.

27. The article of claim 16, wherein the photovoltaically active layer has a thickness of at most about 10 microns.

28. The article of claim 16, further comprising a hole carrier layer between the photovoltaically active layer and the second electrode.

29. The article of claim 28, wherein the hole carrier layer comprises a material selected from the group consisting of spiro-MeO-TAD, triaryl amines, polythiophenes, polyanilines, polycarbazoles, polyvinylcarbazoles, polyphenylenes, polyphenylvinylenes, polysilanes, polythienylenevinylenes, polyisothianaphthanenes, and copolymers or mixtures thereof.

30. The article of claim 29, wherein the hole carrier layer comprises poly(3-hexylthiophene) or poly(3,4-ethylenedioxythiophene).

31. The article of claim 16, further comprising a hole blocking layer between the photovoltaically active layer and the first electrode.

32. The article of claim 31, wherein the hole blocking layer comprises LiF, metal oxides, or amines.

33. The article of claim 31, wherein the hole blocking layer comprises a non-porous metal oxide layer.

34. The article of claim 16, wherein the article is configured as a solid state photovoltaic cell.
